(19) United States
(12) Patent Application Publication
(10) Pub. No.: US 2011/0310538 A1
(43) Pub. Date: Dec. 22, 2011

(54) TELEVISION APPARATUS AND ELECTRONIC DEVICE

(75) Inventors: Koji ABE, Oume-shi (JP); Yuji NAKAJIMA, Nishitama-Gun (JP)

(73) Assignee: KABUSHIKI KAISHA TOSHIBA, Tokyo (JP)

(21) Appl. No.: 13/089,003

(22) Filed: Apr. 18, 2011

(30) Foreign Application Priority Data
Jun. 18, 2010 (JP) 2010-139824

(51) Int. Cl. H05K 7/00

(52) U.S. Cl. 361/679.01

(57) ABSTRACT

According to one embodiment, a television apparatus includes a housing and a cover. The housing is provided with an opening for opening a housing portion to house an electronic component. The cover is attached to the housing. The cover is configured to cover the opening, and includes a honeycomb-like rib on the rear face.

### CROSS-REFERENCE TO RELATED APPLICATIONS

This application is based upon and claims the benefit of priority from Japanese Patent Application No. 2010-139824, filed Jun. 18, 2010, the entire contents of which are incorporated herein by reference.

### FIELD

Embodiments described herein relate generally to a television apparatus and an electronic device.

### BACKGROUND

Typically, known electronic devices have a housing with an opening for opening a housing portion to house an electronic component.

With regard to such electronic devices, there is a desire to increase the rigidity of a portion of a housing where an opening is formed.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of a personal computer (PC) as an electronic device according to a first embodiment;

FIG. 2 is an exemplary plan view of a first main body of the PC viewed from a bottom face side when first and second openings are opened in the first embodiment;

FIG. 3 is an exemplary plan view of the first main body of the PC viewed from the bottom face side when the first opening is covered by a first cover and the second opening is opened in the first embodiment;

FIG. 4 is an exemplary plan view of the first main body of the PC viewed from the bottom face side when the first opening is covered by the first cover and the second opening is covered by a second cover in the first embodiment;

FIG. 5 is an exemplary longitudinal cross-sectional view of the first main body of the PC along line V-V in FIG. 4 in the first embodiment;

FIG. 6A is a cross-sectional view of a portion VIa in FIG. 5 in the first embodiment;

FIG. 6B is a cross-sectional view along line VIb-VIb in FIG. 4 in the first embodiment;

FIG. 7 is an exemplary perspective view of a bottom wall of a housing of the first main body of the PC viewed from an inner surface side (rear face side) of the housing in the first embodiment;

FIG. 8 is an exemplary schematic diagram of the PC illustrated in FIG. 7 to which the first and the second covers are attached in the first embodiment;

FIG. 9 is an exemplary perspective view of the first cover of the PC viewed from the rear face side in the first embodiment;

FIG. 10 is an exemplary plan view of the first cover of the PC viewed from the rear face side in the first embodiment;

FIG. 11 is an exemplary cross-sectional view along line XI-XI illustrated in FIG. 10 in the first embodiment;

FIG. 12 is an exemplary perspective view of the second cover of the PC viewed from the rear face side in the first embodiment;

FIG. 13 is an exemplary plan view of the second cover of the PC viewed from the rear face side in the first embodiment; FIG. 14 is an exemplary plan view of a bottom wall of a housing of a first main body of a PC viewed from an inner surface side (rear face side) of the housing as an electronic device according to a second embodiment; and

FIG. 15 is an exemplary front view of a television apparatus as an electronic device according to a third embodiment.

### DETAILED DESCRIPTION

In general, according to one embodiment, a television apparatus comprises a housing and a cover. The housing is provided with an opening for opening a housing portion to house an electronic component. The cover is attached to the housing. The cover is configured to cover the opening, and comprises a honeycomb-like rib on the rear face.

According to another embodiment, an electronic device comprises a housing and a cover. The housing is provided with an opening for opening a housing portion to house an electronic component. The cover is attached to the housing. The cover is configured to cover the opening, and comprises a honeycomb-like rib on the rear face.

In the embodiments described below, the identical constituent elements are referred to by the same reference numerals, and repetition is avoided in the explanation of such constituent elements.

A personal computer (PC) 1 as an electronic device according to a first embodiment will now be described. While the electronic device of the first embodiment will be described as the PC 1, it is not so limited and may be, for example, televisions, desktop PCs, personal digital assistants (PDAs), smartbooks, smartphones, or cellular phones.

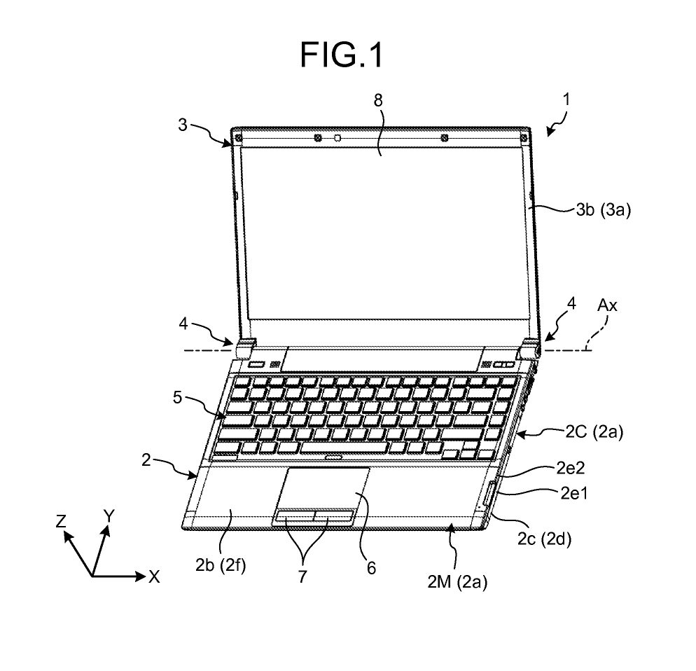

As illustrated in FIG. 1, the notebook PC 1 as an electronic device of the first embodiment comprises a rectangular and flat first main body 2 and a rectangular and flat second main body 3. The first main body 2 and the second main body 3 are connected to be relatively rotatable around a rotation axis Ax via a hinge mechanism 4. In the present embodiment, for convenience sake, the width direction (left-right direction) of the first main body 2 is referred to as X direction, the end direction of the first main body 2 is referred to as Y direction, and the thickness direction of the first main body 2 is referred to as Z direction. The X axis, the Y axis, and the Z axis are perpendicular to one another.

In the first main body 2, a keyboard 5, a pointing device 6, click buttons 7, and the like are arranged in an exposed manner on an upper surface 2b that is an external face of a housing 2a. In the second main body 3, a display panel 8 such as a liquid crystal display (LCD) is arranged as a display device in an exposed manner on a front face 3b that is an external face of a housing 3a. In the open state illustrated in FIG. 1, the keyboard 5, the pointing device 6, the click buttons 7, the display panel 8, and the like lie in an exposed condition such that the user can use them. In contrast, in a folded state, the upper surfaces 2b and 3b face each other from up close in such a way that the keyboard 5, the pointing device 6, the click buttons 7, the display panel 8, and the like are hidden by the housings 2a and 3a.

The first main body 2 has a rectangular shape long in the X direction and short in the Y direction in a plan view from the Z direction, and is formed in a thin flat shape in the Z direction. The housing 2a of the first main body 2 comprises a first split body 2C and a second split body 2M. The first split body 2C has a bottom wall 2d forming a lower surface 2c and a side wall 2e1 projected at the peripheral portion of the bottom wall 2d. The second split body 2M has a ceiling wall 2f forming the upper surface 2b and a side wall 2e2 projected at the peripheral portion of the ceiling wall 2f.

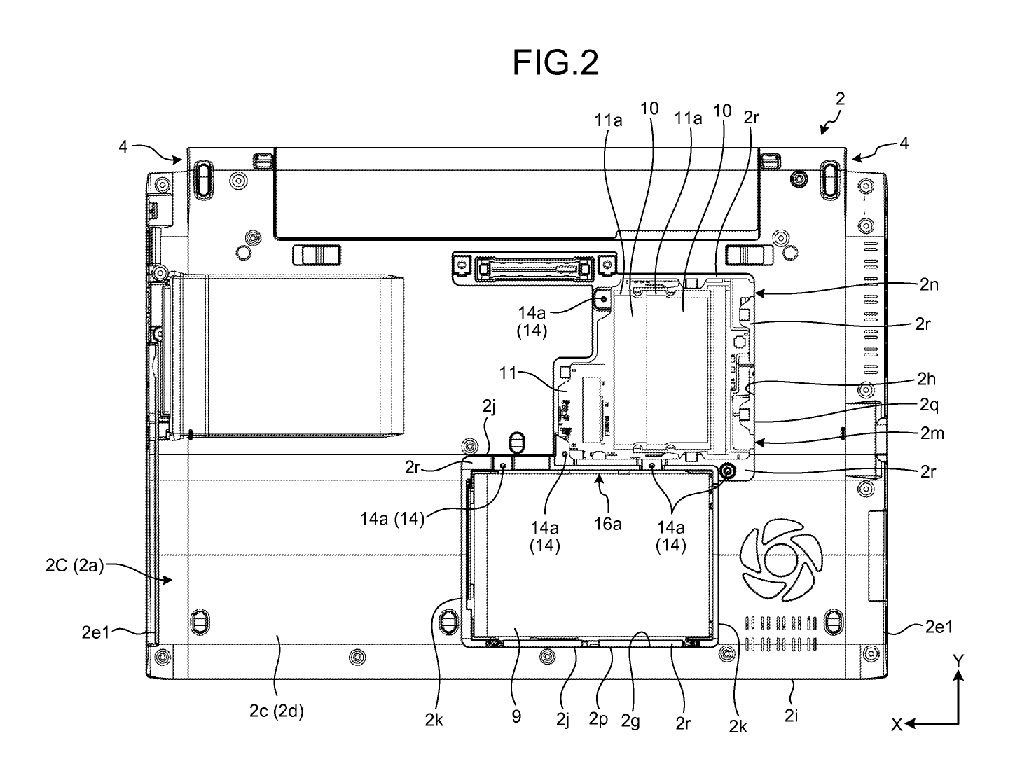

As illustrated in FIG. 2, a first opening 2g and a second opening 2h are formed at the bottom wall 2d of the housing 2a. The first opening 2g is located near an end edge 2i at an end distantly positioned from the hinge mechanism 4 of the first main body 2. The first opening 2g is formed in a rectangular shape having a long side 2j along the end edge 2i and a short side 2k perpendicular to the long side 2j in a plan view from the side of the lower surface 2c (Z direction). The long side 2j extends in the X direction and the short side 2k extends in the Y direction.

The second opening 2h is disposed adjacent to the side of the hinge mechanism 4 (base end side) of the first opening 2g. The second opening 2h is formed in an L-shape in which a rectangular portion 2m whose width in the X direction is wide at the side near the first opening 2g and a rectangular portion 2n whose width in the X direction is narrow at the side near the hinge mechanism 4, in a plan view from the side of the lower surface 2c (Z direction).

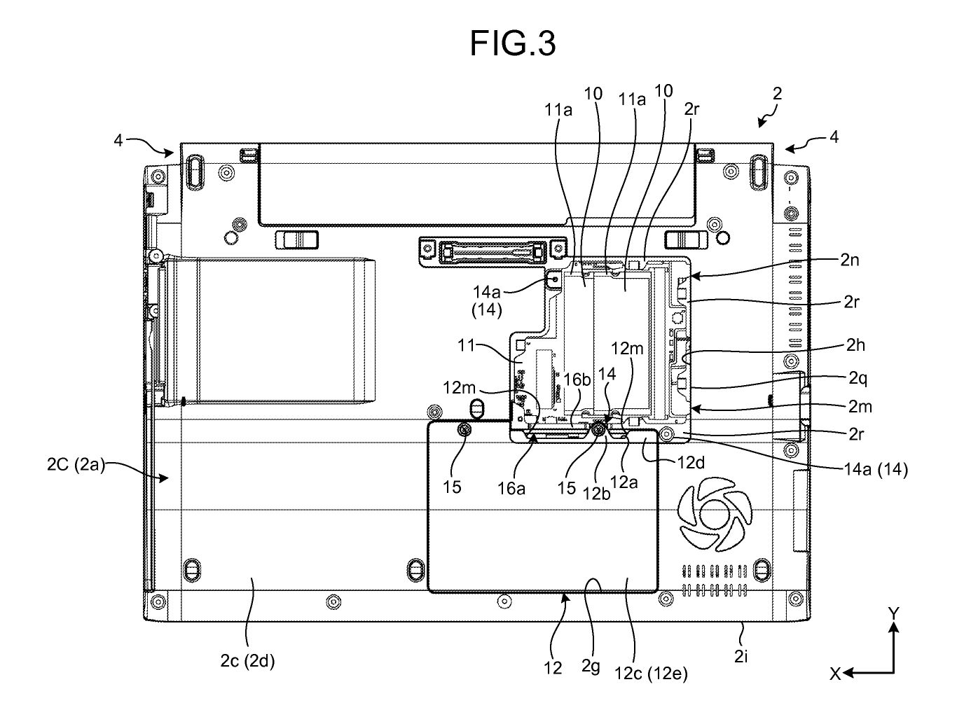

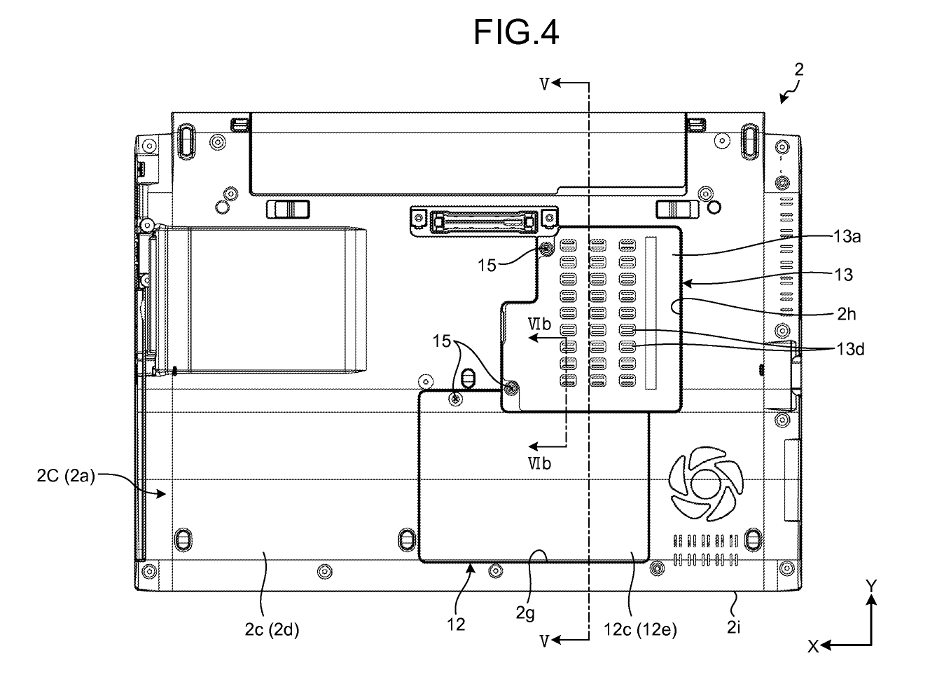

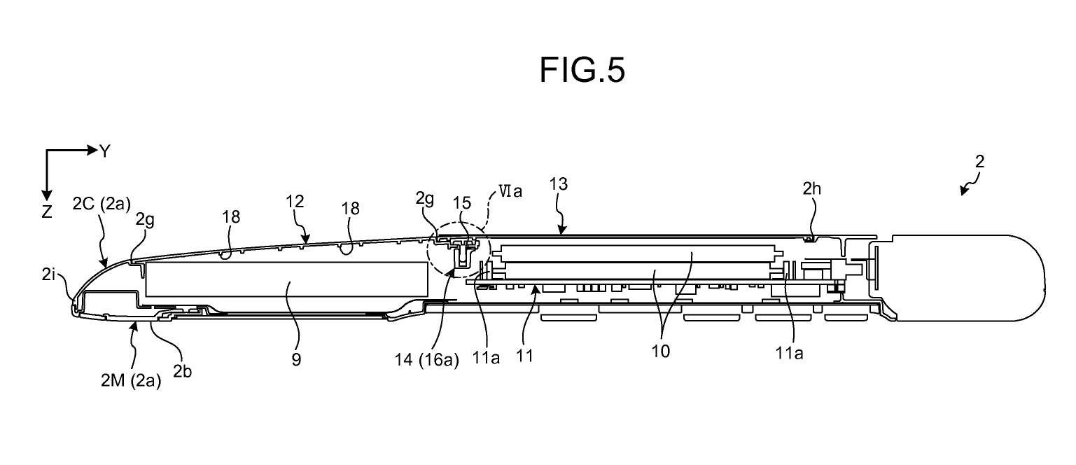

As illustrated in FIGS. 2 and 5, the first opening 2g opens a housing portion to house a hard disk drive (HDD) 9 as an electronic component in the housing 2a, and the second opening 2h opens a housing portion to house memory 10 as an electronic component in the housing 2a. The memory 10 is detachably attached to a memory socket 11a mounted on a circuit board 11. In other words, the first opening 2g and the second opening 2h are openings for attaching and detaching electronic components. The first opening 2g is covered by a first cover 12 (see FIGS. 3 and 4) and the second opening 2h is covered by a second cover 13 (see FIG. 4).

As illustrated in FIG. 2, an inward flange portion 2r positioned at the inner side of the housing than the lower surface 2c is provided along peripheries 2p and 2q. The flange portion 2r has female screw holes 14a. Screws 15 (see FIGS. 3 and 4) for fixing the first cover 12 and the second cover 13 are engaged with the female screw holes 14a. In the present embodiment, the screws 15 are fastening members and the female screw holes 14a are fixed portions corresponding to the fastening members . An bridge frame 16a is formed on a boundary between the first opening 2g and the second opening 2h in the X direction. The first opening 2g and the second opening 2h are split by the strip-shaped bridge frame 16a extending in the X direction.

The first cover 12 is supported by the flange portion 2r of the first opening 2g and the bridge frame 16a. In other words, the flange portion 2r and the bridge frame 16a are peripheral supporting portions of the first cover 12.

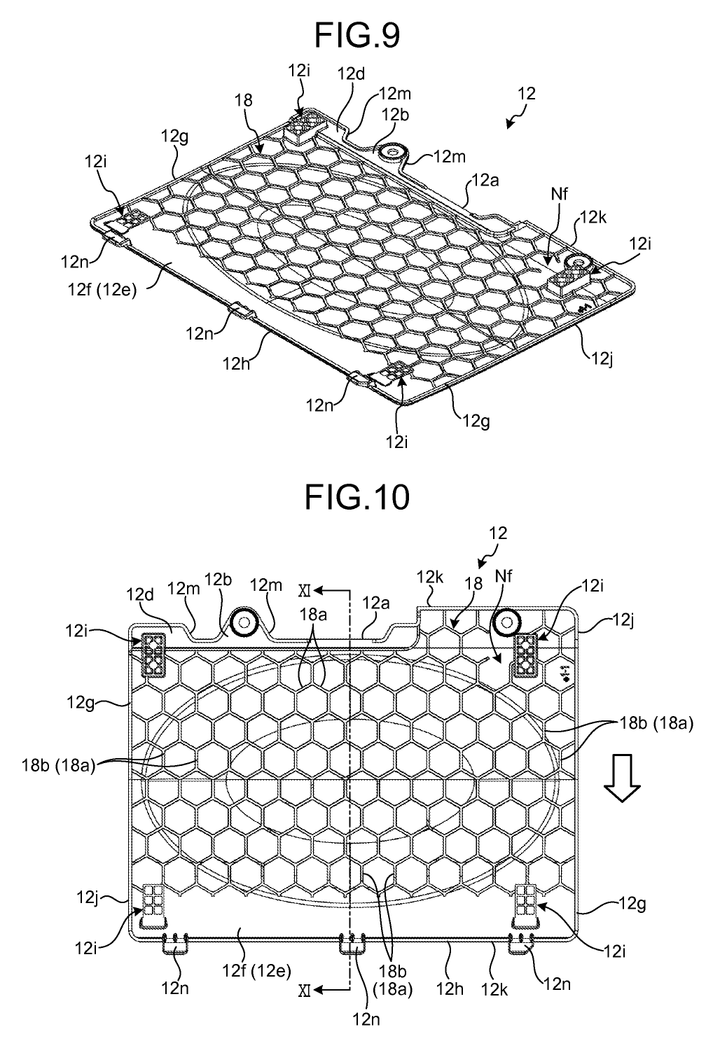

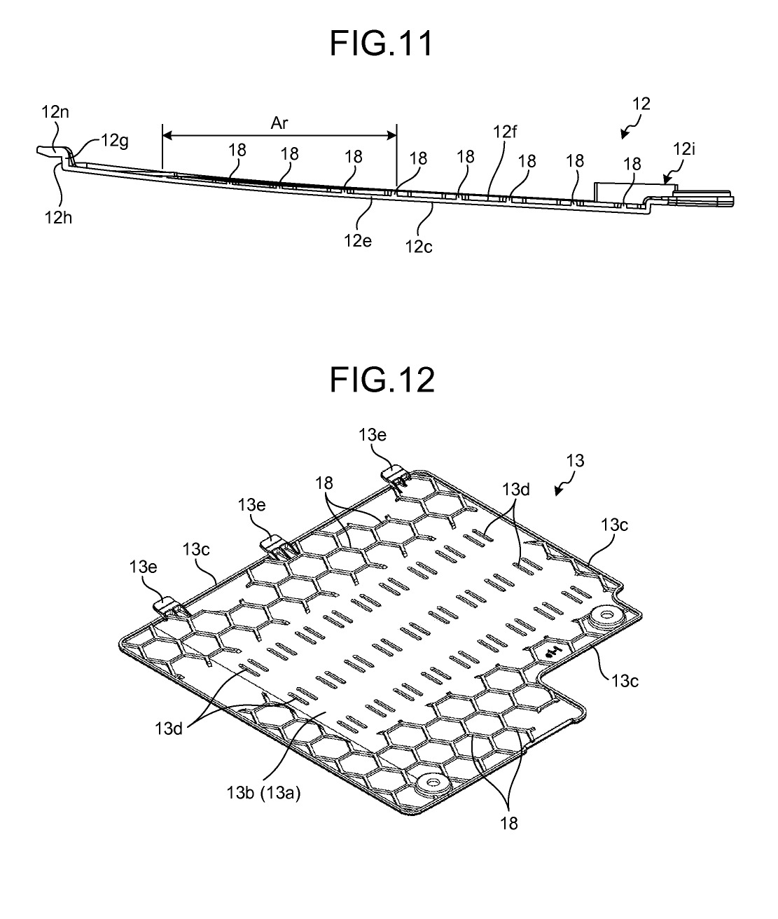

As illustrated in FIGS. 2 to 5, in the present embodiment, the first cover 12 is disposed on a boss portion 14 placed at an intermediate portion of the bridge frame 16a, and the second cover 13 is disposed on the first cover 12. Accordingly, to open the first opening 2g, the user or the like first removes the second cover 13 from the closed state in FIG. 4 (in the state of FIG. 3), and then removes the first cover 12 (in the state of FIG. 2). On the other hand, to attach the first and the second covers 12 and 13, the user first attaches the first cover 12 from the opened state in FIG. 2 (in the state of FIG. 3), and then attaches the second cover 13 (in the state of FIG. 4). In the present embodiment, the bridge frame 16a, the first cover 12, and the second cover 13 overlap each other at the boundary between the first opening 2g and the second opening 2h, which increases the rigidity of the housing 2a. The first cover 12 and the second cover 13 are fixed to the housing 2a by being engaged with the edges of the first opening 2g and the second opening 2h by engagement claws 12n and 13e (see FIGS. 9, 12, and the like), and by fixing with the screws 15.

As illustrated in FIG. 3, a tongue-piece-shaped arm portion 12b projected from an end edge 12a at the side of the second opening 2h toward the bridge frame 16a is formed on the first cover 12. The arm portion 12b is mounted on the boss portion 14 (see FIG. 2). The female screw hole 14a is formed in the boss portion 14. The screw 15 passing through a through hole formed in the arm portion 12b is screwed into the female screw hole 14a, and the arm portion 12b is fixed to the boss portion 14 or the bridge frame 16a. An outward flange portion 12d positioned at the inner side of the housing than a surface 12c of the first cover 12 is formed on an end edge at the side of the second opening 2h of the first cover 12.

The second cover 13 is supported by the bridge frame 16a, the flange portion 12d of the first cover 12, and the flange portion 2r of the bottom wall 2d. In other words, the bridge frame 16a, the flange portion 12d, and the flange portion 2r are peripheral supporting portions of the second cover 13.

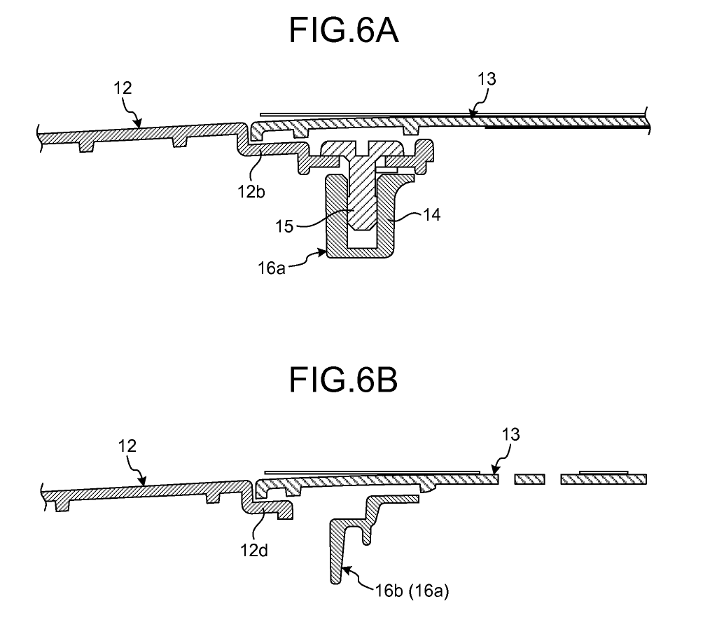

In the present embodiment, as illustrated in FIGS. 3 and 6A, the boss portion 14 formed on the bridge frame 16a corresponds to a first cover supporting portion for supporting the first cover 12, and as illustrated in FIGS. 3 and 6B, a strip portion 16b of the bridge frame 16a excluding the boss portion 14 corresponds to a second cover supporting portion for supporting the second cover 13. In this manner, by dividing the boss portion 14 that is the first cover supporting portion and the strip portion 16b that is the second cover supporting portion in the long-side direction (stretching direction, or the X direction in the present embodiment) of the bridge frame 16a, it is easier to make the width of the bridge frame 16a narrower, compared to when the two cover supporting portions are divided in the short-side direction (width direction) of the bridge frame 16a. Accordingly, not only the first opening 2g and the second opening 2h but also the housing portion of the HDD 9 and the housing portion of the memory 10 in the housing 2a can be arranged closer to each other. As illustrated in FIG. 3, a notch 12m is formed on the end edge 12a at the side of the bridge frame 16a of the first cover 12, in addition to the arm portion 12b and the like. Accordingly, not only the first cover 12 but also the first main body 2 can be made lightweight. In other words, a structure is realized in which the first and the second openings 2g and 2h are disposed close to each other and a required rigidity can be easily obtained at the boundary between the first and the second openings 2g and 2h with a relatively lightweight structure.

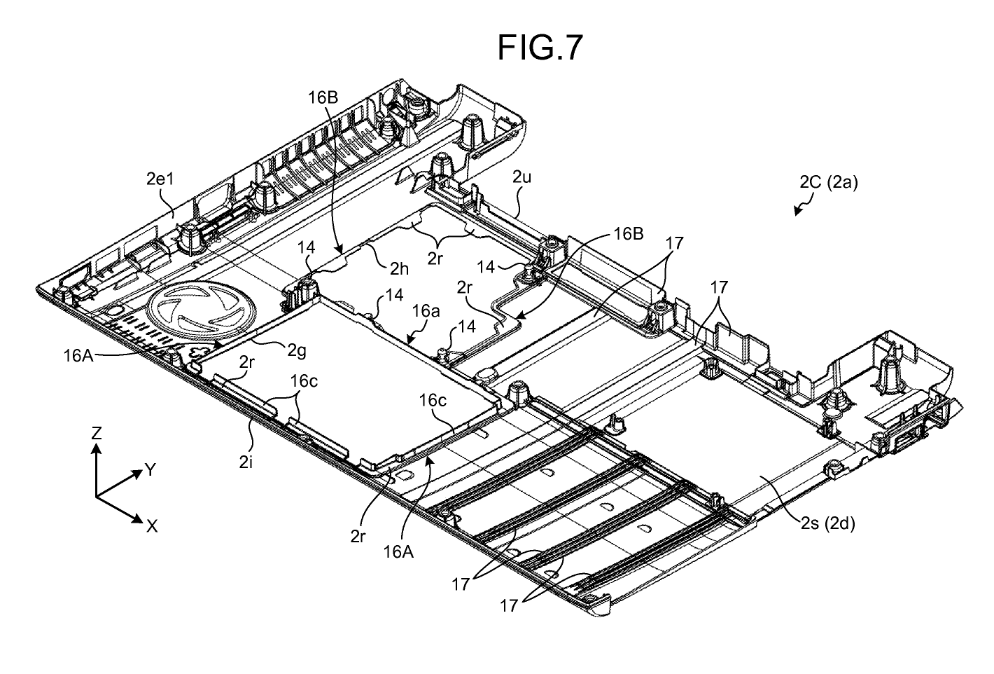

As illustrated in FIG. 7, ribs 17 projected in a wall shape or a ridge shape toward the inner side of the housing 2a are formed on a rear face 2s of the bottom wall 2d of the first split body 2C. Frames 16A and 16B projected on the rear face 2s and having bent cross-sections are formed on the peripheral portions of the first and the second openings 2g and 2h. The frames 16A and 16B, and the ribs 17 are connected to each other, and function as skeleton members in a ladder-shape or a grid-shape. Accordingly, the rigidity of the bottom wall 2d is increased. The frame 16A is connected to the end edge 2i at the end of the bottom wall 2d and the frame 16B is connected to an end edge 2u at the base end of the bottom wall 2d of the frame 16B, thereby connecting the frames 16A and 16B to each other. Consequently, in the present embodiment, the frames 16A and 16B are connected to each other and installed between the end edge 2i at the end and the end edge 2u at the base end side, at an area where the first and the second openings 2g and 2h are formed on the bottom wall 2d. As a result, the rigidity is increased. The frame 16A also has a vertical wall 16c bent and extended toward the inner side of the housing 2a at the end of the inward flange portion 2r. As a result, the rigidity is further increased. A plurality of boss portions 14 on each which the female screw hole 14a (see FIG. 2) for engaging with the screw 15 is formed are connected to the frames 16A and 16B. As a result, the rigidity of the bottom wall 2d is increased, and the stable engagement between the first and the second covers 12 and 13 with the bottom wall 2d is improved. The first and the second split bodies 2C and 2M are made of a metal material a synthetic resin, and the like (such as magnesium alloy).

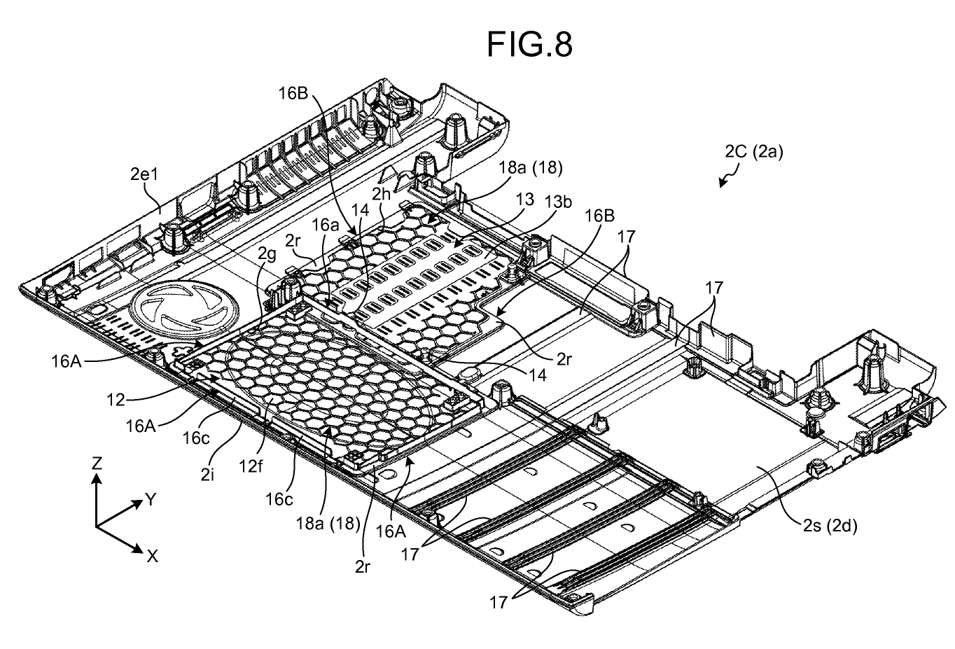

As illustrated in FIGS. 8 to 10, 12, 13, and the like, honeycomb-like ribs 18 are formed on rear faces 12f and 13b of bottom walls 12e and 13a of the first and the second covers 12 and 13. The honeycomb-like ribs 18 are formed so that a plurality of vertical walls 18a projected on the rear faces 12f and 13b are formed in a shape in which hexagons are closely conjoined together in a plan view relative to the rear faces 12f and 13b. The ribs 18 can be formed over the entire area of the rear faces 12f and 13b of the first and the second covers 12 and 13 excluding a partially provided non-forming region. The first and the second covers 12 and 13 are made of a metal material and a synthetic resin, and the like (such as magnesium alloy).

As illustrated in FIGS. 9 and 10, in the first cover 12, the honeycomb-like ribs 18 are formed over substantially the entire area of the rear face 12f, excluding a region along an end edge 12h positioned at the end of the housing 2a. In the first cover 12, the ribs 18 are connected to a peripheral wall 12g formed at the periphery of the first cover 12 excluding the side of the end edge 12h. The first cover 12 has a region Ar in which the height of the ribs 18 gradually decreases from the intermediate portion toward the side of the end edge 12h at the end in the Y direction. With such a structure, it is possible to prevent the stress concentration from occurring due to a sudden change in the height of the ribs 18. In the present embodiment, as illustrated in FIG. 5, the height of the inner space of the housing 2a gradually decreases from the intermediate portion toward the end edge 2i at the end in the Y direction. With the region Ar formed on the first cover 12, in which the height of the ribs 18 gradually decreases, the height of the space for housing the HDD 9 can be easily obtained. The height of the ribs 18 is constant in a region other than the region Ar.

A non-forming region Nf is partially formed in the forming region of the ribs 18 in the first cover 12. For example, a gasket (not illustrated) that is an intervening component having elasticity and conductivity is adhered to the non-forming region Nf . With such a structure, a ground potential can be commonly used between the first cover 12 and the housing 2a, and the HDD 9 (see FIG. 5) housed in the housing portion covered by the first cover 12. Attaching the intervening component on the non-forming region Nf of the ribs 18 enables more stable mounting than direct mounting on the ribs 18 thanks to the increased contact area. A buffer member (not illustrated) having elasticity may be mounted on a projection portion 12i in a prism shape projected from four corners of the first cover 12. The buffer member can prevent a large load from being applied to the HDD9 from the first cover 12.

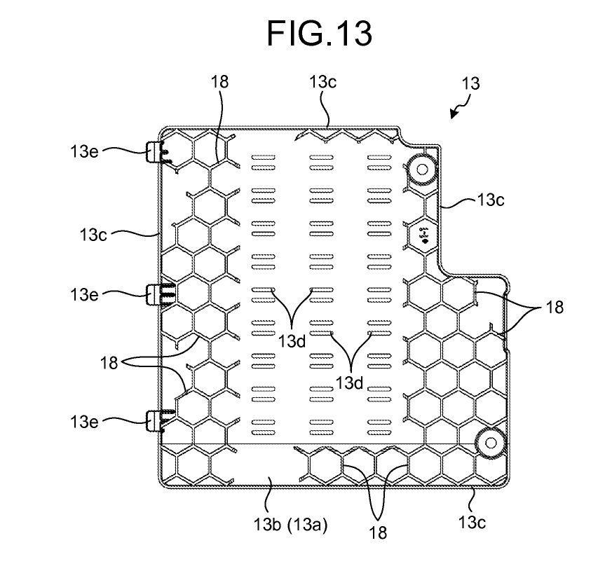

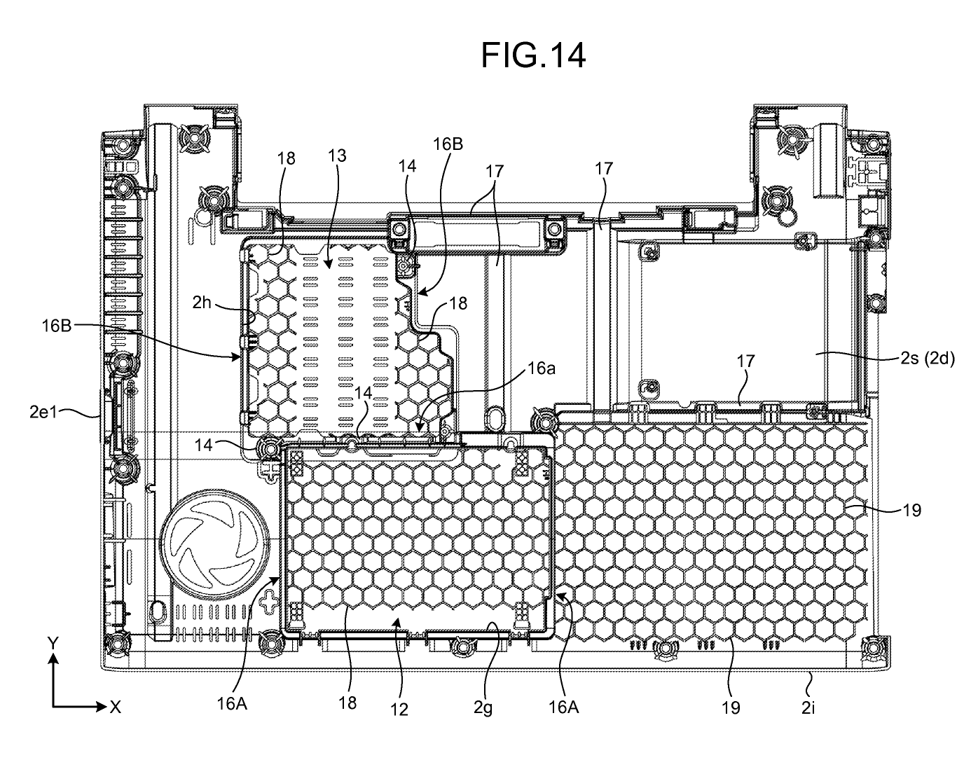

As illustrated in FIGS. 12 and 13, the honeycomb-like ribs 18 are formed on the second cover 13 excluding the center portion of the rear face 13b. In the second cover 13, the ribs 18 are connected to a peripheral wall 13c formed at the periphery of the second cover 13. In the second cover 13, the height of the ribs 18 is constant. Air holes 13d that are through holes are formed on the center portion of the second cover 13 where the ribs 18 are not formed.

As illustrated in FIG. 8, in the present embodiment, the peripheral portions of the first and the second covers 12 and 13 that cover the first and the second openings 2g and 2h are overlapped with the frames 16A and 16B formed on the peripheral portions of the first and the second openings 2g and 2h. In other words, the inward flange portion 2r that is a part of the frames 16A and 16B and the peripheral portion of the honeycomb-like ribs 18 overlap each other at the peripheral portions of the first and the second covers 12 and 13. Accordingly, the load applied to the first and the second covers 12 and 13 is applied to the frames 16A and 16B through the ribs 18, thereby increasing the load resistance and impact resistance of the first and the second covers 12 and 13. Particularly, since the vertical wall 16c of the frame 16A and the honeycomb-like ribs 18 overlap each other at the peripheral portion of the first opening 2g, it is possible to further increase the load resistance and impact resistance.

As apparent from FIGS. 10, 3, 4, and the like, in the present embodiment, the first cover 12 is formed in a rectangular shape and the honeycomb-like ribs 18 are arranged to comprise vertical walls 18b formed in parallel with a short side 12j of the rectangular first cover 12, as vertical walls 18a forming a unit hexagon. To manufacture the first cover 12 by molding (die-casting), for example, as illustrated in a white arrow in FIG. 10, when molten metal is poured into a mold (not illustrated) from one long side 12k to another long side 12k, the flow resistance of the molten metal can be reduced by providing such an orientation. In an orientation comprising the vertical walls 18a perpendicular to the direction to which the molten metal is poured, the flow resistance of the molten metal is increased. When the molten metal is poured along the long side 12k, even if the orientation comprises the vertical walls formed in parallel with the long side 12k as the vertical walls 18a forming a unit hexagon, the distance during which the molten metal flows is elongated, thereby increasing manufacturing defects. In the present embodiment, the honeycomb-like ribs 18 are arranged in the orientation comprising the vertical walls 18b formed in parallel with the short side 12j of the rectangular first cover 12 as the vertical walls 18a forming a unit hexagon. Accordingly, the first cover 12 on which the honeycomb-like ribs 18 are formed can be manufactured more efficiently.

As described above, according to the first embodiment, the honeycomb-like ribs 18 are formed on at least one (both in the present embodiment) of the rear faces 12f and 13b of the first and the second covers 12 and 13 that cover the first and the second openings 2g and 2h. Accordingly, the rigidity of at least one (both in the present embodiment) of the first and the second covers 12 and 13 can be effectively increased by the honeycomb-like ribs 18.

In the present embodiment, the frames 16A and 16B projected from the rear face 2s of the housing 2a to the inner side of the housing 2a are formed on the peripheral portion of at least one (both in the present embodiment) of the first and the second openings 2g and 2h. Accordingly, the rigidity of the housing 2a can be further increased at a portion where the first and the second openings 2g and 2h are formed by the frames 16A and 16B.

In the present embodiment, the frames 16A and 16B and the honeycomb-like ribs 18 overlap each other when at least one (both in the present embodiment) of the first and the second openings 2g and 2h is closed. Accordingly, the load applied to the first or the second cover 12 or 13 can be transmitted to the frames 16A and 16B through the ribs 18, thereby further increasing the load resistance and impact resistance of the first and the second covers 12 and 13.

In the present embodiment, the region Ar in which the height of the ribs 18 gradually decreases along the rear face 12f is formed on the first cover 12. Accordingly, it is possible to prevent the stress concentration from occurring due to a sudden change in the height of the ribs 18. The height of the ribs 18 gradually decreases from the center side to the peripheral portion side of the housing 2a in the region Ar where the height of the ribs 18 gradually decreases. Consequently, when the thickness of the peripheral portion of the housing 2a is thinner than the thickness of the center portion, the height of the component housing portion in the housing 2a can be more easily obtained.

In the present embodiment, the second opening 2h adjacent to the first opening 2g is formed in the housing 2a. When the first cover 12 and the second cover 13 are closed, a part of the peripheral portion of the first cover 12 and a part of the peripheral portion of the second cover 13 overlap each other. Since the first and the second covers 12 and 13 overlap each other, it is possible to further increase the rigidity of the housing 2a at the boundary between the first and the second openings 2g and 2h.

In the present embodiment, the bridge frame 16a extends over the boundary between the first and the second openings 2g and 2h is formed on the bottom wall 2d of the housing 2a. Accordingly, the rigidity of the housing 2a can be further increased at the boundary between the first and the second openings 2g and 2h, and the bridge frame 16a can be used to support the first and the second covers 12 and 13. In the present embodiment, the boss portion 14 that is the first cover supporting portion on which the first cover 12 is mounted and the strip portion 16b that is the second cover supporting portion on which the second cover 13 is mounted are formed on the bridge frame 16a in the extending direction of the bridge frame 16a. Accordingly, compared to when the two cover supporting portions are divided in the short-side direction (width direction) of the bridge frame 16a, it is easier to make the width of the bridge frame 16a narrower. Consequently, not only the first and the second openings 2g and 2h, but also the component housing portions corresponding to the first and the second openings 2g and 2h in the housing 2a can be arranged closer to each other more easily.

In the present embodiment, the end edge 12a on the side of the bridge frame 16a of one of the first and the second covers 12 and 13 (first cover 12 in the present embodiment) is distantly positioned from the bridge frame 16a, and the arm portion 12b supported by the bridge frame 16a is projected from the end edge 12a to the bridge frame 16a. Accordingly, the notch 12m is formed on the end edge 12a on the side of the bridge frame 16a of the first cover 12, in addition to the arm portion 12b and the like. Accordingly, not only the first cover 12 but also the first main body 2 can be made lightweight.

According to a second embodiment, as illustrated in FIG. 14, honeycomb-like second ribs 19 connected to the frame 16A are formed on the rear face 2s of the bottom wall 2d of the housing 2a in a first main body 2A. The second ribs 19 have the same structure as that of the ribs 18 formed on the first cover 12 and are connected to the frame 16A and the ribs 17. According to the second embodiment, the rigidity of the bottom wall 2d can be further increased by the ribs 19, and the load applied to the first cover 12 can be transmitted to the ribs 19 through the ribs 18 and the frame 16A. Accordingly, it is possible to further increase the load resistance and impact resistance of the first cover 12. A PC 1A as an electronic device comprising the first main body 2A of the second embodiment has the same structure as that of the first embodiment except that the ribs 19 are formed, thereby obtaining the same effects as those of the first embodiment.

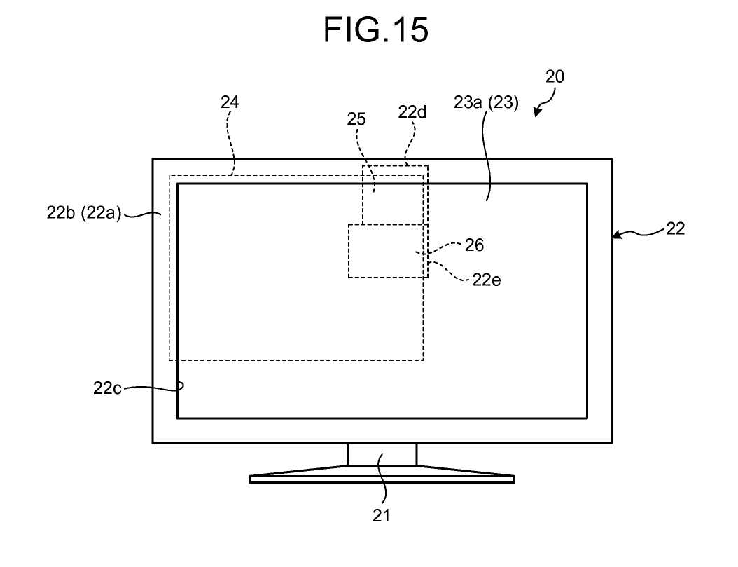

As illustrated in FIG. 15, a television apparatus 20 as an electronic device according to a third embodiment comprises a stand 21 and a main body 22 supported by the stand 21.

A housing 22a of the main body 22 comprises a display panel 23 such as liquid crystal display (LCD) and a circuit board 24. The display panel 23 is a display device (display) having a display screen 23a exposed anteriorly from an opening 22c formed on a front face 22b of the housing 22a The circuit board 24 has electronic components and the like (not illustrated) mounted thereon. The display panel 23 and the circuit board 24 are fixed to the housing 22a with a screw or the like (not illustrated).

The display panel 23 is formed in the shape of a thin flat rectangular parallelepiped in the front-back direction (perpendicular direction to the plane of paper of FIG. 15). The display panel 23 receives video signals from a video signal processing circuit (not illustrated), which is one of the control circuits (not illustrated) configured with the electronic components mounted on the circuit board 24. Then, the display panel 23 displays video including still images and moving images on the display screen 23a that is positioned in the front. Apart from the video signal processing circuit, the control circuit of the television apparatus 20 comprises a tuner module, a high-definition multimedia interface (HDMI) signal processing module, an audio-video (AV) input terminal, a remote control signal receiving module, a control module, a selector, an on-screen display interface, a memory module (such as read only memory (ROM), a random access memory (RAM), or a hard disk drive (HDD)), an audio signal processing circuit, and the like, none of which is illustrated. The circuit board 24 is housed behind (on the rear face side of) the display panel 23 inside the housing 22a. Meanwhile, the television apparatus 20 has built-in amplifiers and speakers (not illustrated) for audio output.

The television apparatus 20 of the third embodiment comprises the frame, the bridge frame, the ribs, and first and the second covers 25 and 26 similar to those of the first embodiment or the second embodiment described above, at the rear face side of the housing 22a. The television apparatus 20 also has a back wall (not illustrated) on which openings 22d and 22e are formed. The first and the second covers 25 and 26 are detachably formed, and block the openings 22d and 22e. Honeycomb-like ribs are formed on the inner surfaces of the first and the second covers 25 and 26. Accordingly, the television apparatus 20 as the electronic device of the third embodiment can also achieve the similar effects as those in the embodiments described above.

Regarding the display, the electronic device, the housing, the openings, the covers, the honeycomb-like ribs, the frames, the ribs on the housing, the region where the height gradually decreases, the vertical walls, the bridge frame, the cover supporting portions, and the arm portion, the specifications (method, structure, shape, material, size, number, direction, type, arrangement, etc.) can be suitably modified.

The various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television apparatus comprising:
a housing comprising an opening portion configured to receive an electronic component; and
a cover attached to the housing, the cover configured to cover the opening, and comprising a honeycomb-like rib on a rear face.

2. The television apparatus of claim 1, wherein
a frame projecting from a rear face of the housing to an inner side of the housing is at a peripheral portion of the opening of the housing, and
the rib and the frame overlap each other when the cover is closed.

3. The television apparatus of claim 1, wherein the cover comprises a region where a height of the rib gradually decreases along the rear face.

4. The television apparatus of claim 3, wherein the height of the rib gradually decreases from a center side to a peripheral side of the housing in the region.

5. The television apparatus of claim 1, wherein
the cover is in a rectangle shape, and
the honeycomb-like rib comprises a vertical wall in parallel with a short side of the rectangle as a vertical wall forming a unit hexagon.

6. The television apparatus of claim 1, wherein a honeycomb-like second rib connected to the frame is on a rear face of the housing.

7. The television apparatus of claim 1, wherein
the housing comprises a second opening adjacent to the opening, and
when the cover and a second cover for covering the second opening are closed, a portion of a peripheral portion of the cover and a portion of a peripheral portion of the second cover overlap each other.

8. The television apparatus of claim 7, wherein
the housing comprises a bridge frame extending over a boundary between the opening and the second opening; and
the bridge frame comprises a first cover supporting portion on which the cover is mounted and a second cover supporting portion on which the second cover is mounted in an extending direction of the bridge frame.

9. The television apparatus of claim 8, wherein
an end edge on a side of the bridge frame of one of the cover and the second cover is separate from the bridge frame, and
an arm portion extending toward the bridge frame and supported by the bridge frame is provided on the end edge.

10. An electronic device comprising:
a housing comprising an opening configured to receive an electronic component; and
a cover attached to the housing, the cover configured to cover the opening, and comprising a honeycomb-like rib on a rear face.
